(19) United States
(12) Patent Application Publication
(10) Pub. No.: US 2020/0411413 A1
(43) Pub. Date: Dec. 31, 2020

(54) SUBSTRATE FOR AN ELECTRONIC DEVICE

(71) Applicants: Amruthavalli Pallavi Alur, Tempe, AZ (US); Brandon C. Marin, Chandler, AZ (US); Yikang Deng, Chandler, AZ (US); Liwei Cheng, Chandler, AZ (US); Jeremy D. Ecton, Gilbert, AZ (US); Andrew J. Brown, Phoenix, AZ (US); Lauren A. Link, Mesa, AZ (US); Cheng Xu, Chandler, AZ (US); Prithwish Chatterjee, Tempe, AZ (US); Ying Wang, Chandler, AZ (US)

(72) Inventors: Amruthavalli Pallavi Alur, Tempe, AZ (US); Brandon C. Marin, Chandler, AZ (US); Yikang Deng, Chandler, AZ (US); Liwei Cheng, Chandler, AZ (US); Jeremy D. Ecton, Gilbert, AZ (US); Andrew J. Brown, Phoenix, AZ (US); Lauren A. Link, Mesa, AZ (US); Cheng Xu, Chandler, AZ (US); Prithwish Chatterjee, Tempe, AZ (US); Ying Wang, Chandler, AZ (US)

(21) Appl. No.: 16/454,705

(22) Filed: Jun. 27, 2019

(51) Int. Cl. H01L 23/48; H01L 23/522; H01L 23/528; H01L 21/768

(52) U.S. Cl. CPC H01L 23/481; H01L 21/76898; H01L 23/5283; H01L 23/5226

(57) ABSTRACT

A substrate for an electronic device may include a first layer, and the first layer may include dielectric material. The first layer may include a first interconnect, and the first interconnect may have a first interconnect profile. The substrate may include a second layer, and the second layer may include dielectric material. The second layer may include a second interconnect, and the second interconnect may have a second interconnect profile. The first interconnect profile may be indicative of a subtractive manufacturing operation and the second interconnect profile may be indicative of an additive manufacturing operation.

### BACKGROUND

An electronic device may include a semiconductor die (e.g., integrated circuit, or the like). The semiconductor die may be coupled to a circuit board. The circuit board may route an electrical signal between the die and other components of the electronic device (e.g., a battery, a display, or the like). The circuit board may route a power signal to the die, for instance to provide the die with energy to operate the die.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates an example of a substrate during a manufacturing operation, according to one embodiment of the present subject matter.

FIG. 2 illustrates an example of the substrate of FIG. 1 during a manufacturing operation, according to one embodiment of the present subject matter.

FIG. 3 illustrates an example of the substrate of FIG. 1 during a manufacturing operation, according to one embodiment of the present subject matter.

FIG. 4 illustrates an example of the substrate of FIG. 1 during a manufacturing operation, according to one embodiment of the present subject matter.

FIG. 5 illustrates an example of the substrate of FIG. 1 during a manufacturing operation, according to one embodiment of the present subject matter.

FIG. 6 illustrates an example of the substrate of FIG. 1 during a manufacturing operation, according to one embodiment of the present subject matter.

FIG. 7 illustrates an example of the substrate of FIG. 1 during a manufacturing operation, according to one embodiment of the present subject matter.

FIG. 9 shows one example of a method 900 for manufacturing an electronic device.

FIG. 10 illustrates a system level diagram, depicting an example of an electronic device including the substrate 100 of FIG. 1 or the electronic device of FIG. 8 as described in the present disclosure.

### DETAILED DESCRIPTION

The present inventors have recognized, among other things, that a problem to be solved can include providing energy to a semiconductor die. The present inventors have recognized, among other things, that a problem to be solved can include providing a substrate with asymmetric interconnects (e.g., pads, contacts, pillars, vias, or the like). The present subject matter can help provide a solution to these problems, such as by providing a substrate for an electronic device. The substrate may include a first layer, and the first layer may include dielectric material. The first layer may include a first interconnect, and the first interconnect may have a first interconnect profile. The substrate may include a second layer, and the second layer may include dielectric material. The second layer may include a second interconnect, and the second interconnect may have a second interconnect profile. The first interconnect profile may be indicative of a subtractive manufacturing operation (e.g., etching, or the like) and the second interconnect profile may be indicative of an additive manufacturing operation (e.g., plating, filling, or the like).

The first interconnect may have a reduced electrical resistance (e.g., to a direct current, an alternating current, or the like). Reducing the electrical resistance of the first interconnect may improve the performance of an electronic device, for example by improving the energy efficiency of the electronic device.

The first interconnect and the second interconnect may be asymmetrical. For example, the first interconnect may have a trapezoidal shape, and the second interconnect may have a rectangular shape. The first interconnect may have a differing dimension (e.g., thickness, width, height, or the like) in comparison to the second interconnect. A method for manufacturing the substrate may facilitate manufacturing of the first interconnect that may be asymmetric to the second interconnect. The method for manufacturing the substrate may improve the efficiency of the manufacturing operation of the substrate. Accordingly, the method for manufacturing the substrate may help improve the yield from manufacturing operations, may help increase the production rate for manufacturing the substrate, reduce a number of operations to manufacture the substrate, or the like.

This overview is intended to provide an overview of subject matter of the present patent application. It is not intended to provide an exclusive or exhaustive explanation of the invention. The detailed description continues, and provides further information about the present patent application.

FIG. 1 illustrates an example of a substrate 100 during a manufacturing operation, according to one embodiment of the present subject matter. The substrate 100 may include a plurality of layers 110. For example, the layers 110 may include a first layer 110A and may include a second layer 110B. The layers 110A, 110B may be coupled to a core 120 of the substrate 100. For example, the layer 110A may be coupled to a first side 121 of the core 120, and the layer 110B may be coupled to a second side 122 of the core 120. The core 120 may include additional layers 110 of the substrate 100. The core 120 may include a cloth material 130 (e.g., a glass, fiberglass, polymer, or the like), and the cloth material 130 may help improve the mechanical properties (e.g., strength, or the like) of the substrate 100. The cloth material 130 may be arranged in a grid, mesh, net, or the like.

The first layer 110A may include a dielectric material 140 (e.g., a polymeric material, or the like). The dielectric material 140 may have a thickness within a range of approximately 5 micrometers to 1 millimeter (e.g., 5 micrometers to 8 micrometers, 10 micrometers, 10 micrometers to 100 micrometers, or the like). The dielectric material 140 may help provide electrical insulation between layers 110 of the substrate. The dielectric material 140 may help improve the mechanical performance of the substrate 100. The cloth material 130 of the core 120 may be impregnated with dielectric material (e.g., the dielectric material 140).

The first layer 110A may include a conductive layer 150 (e.g., copper, aluminum, nickel, gold, or the like, or a combination thereof). The conductive layer 150 may be coupled to the dielectric material 140. The conductive layer 150 may be a foil, and the foil may have a grain structure that is observable. The grain structure of the conductive layer 150 may be indicative of the conductive layer 150 having undergone one or more manufacturing operations (e.g., rolling, squeezing, drawing, extruding, or the like) to produce the foil, for instance the grain structure may be elongated in comparison to a conductive layer 150 that has not been manufactured into a foil. The conductive layer 150 may have a thickness within a range of approximately 5 micrometers to 1 millimeter (e.g., 5 micrometers to 8 micrometers, micrometers, 10 micrometers to 100 micrometers, or the like).

The second layer 110B may be coupled to the core 120. The second layer 110B may be coupled to the first layer 110A. The second layer 110B may include the dielectric material 140. The dielectric material 140 of the first layer 110A may be different than (e.g., a different composition than) the dielectric material 140 of the second layer 110B.

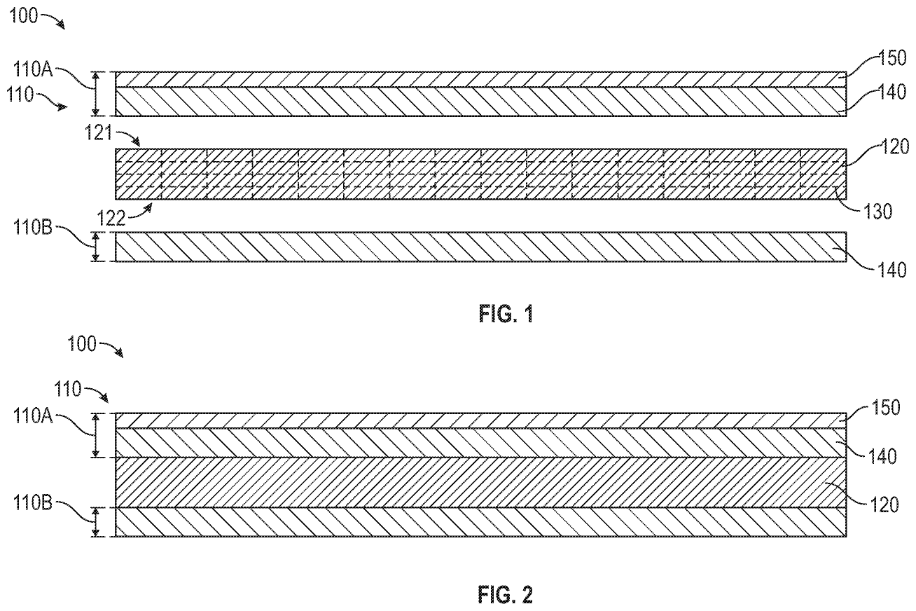

FIG. 2 illustrates an example of the substrate 100 of FIG. 1 during a manufacturing operation, according to one embodiment of the present subject matter. As described herein, the first layer 110A and the second layer 110B may be coupled to the core 120. The dielectric material 140 of the first layer 110A may be located between the conductive layer 150 and the core 120. A thickness of the first layer 110A may be greater than a thickness of the second layer 110B, for instance because the first layer 110A includes the conductive layer 150.

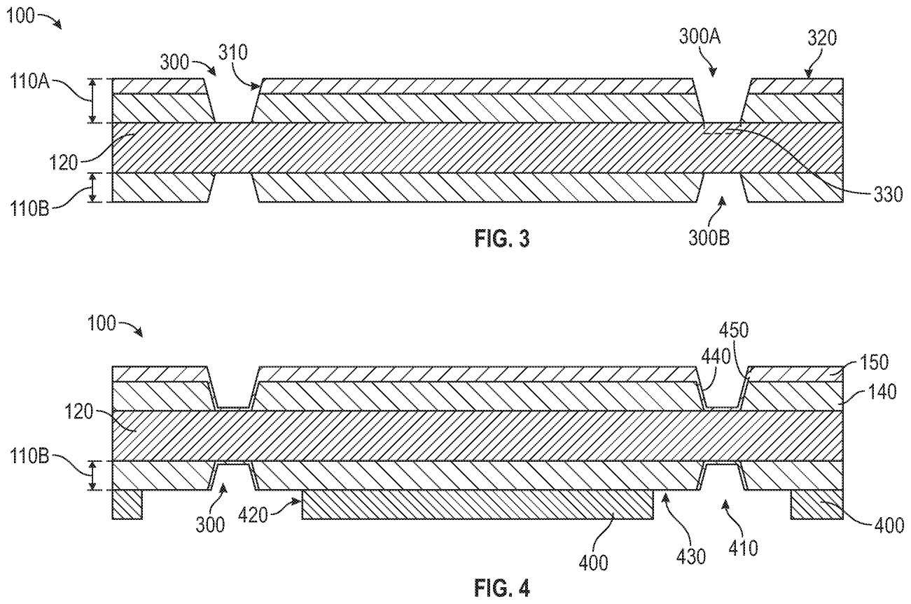

FIG. 3 illustrates an example of the substrate 100 of FIG. 1 during a manufacturing operation, according to one embodiment of the present subject matter. The substrate 100 may define a recess 300. Material (e.g., the conductive layer 150 or the dielectric material 140) may be removed from the substrate 100 to define the recess 300. For example, a laser may ablate the conductive layer 150 and the dielectric material 140 to define the recess 300. The recess 300 may be defined mechanically, for instance by drilling the substrate 100 to remove a portion of the substrate 100. The substrate 100 may define one or more of the recess 300. For example, a first recess 300A may be defined by the first layer 110A, and a second recess 300B may be defined by the second layer 110B.

The recess 300 may have a tapered profile. For example, a sidewall 310 of the recess 300 may be angled with respect to other features of the substrate 100, for instance a surface of the first layer 110A. The recess 300 may have a tapered profile as a result of a manufacturing operation used to define the recess 300. For example, a laser ablation operation may ablate the substrate 100 and the laser ablation operation may result in the recess 300 having a tapered profile.

The recess 300 may interface with the core 120. For example, the recess 300A may extend through a thickness of the first layer 110A. The recess 300 may interface with a core interconnect 330 of the core 120. The substrate 100 may transmit one or more electrical signals, and the core interconnect 330 may help facilitate transmission of the electrical signals within the substrate 100. As described in greater detail herein, the recess 300 may help facilitate interconnecting the core interconnect 300 with additional components of the substrate 100.

FIG. 4 illustrates an example of the substrate 100 of FIG. 1 during a manufacturing operation, according to one embodiment of the present subject matter. A resist material 400 (e.g., a positive photoresist, a negative photoresist, or the like) may be coupled to the substrate 100. For example, the resist material 400 may be coupled to the second layer 110B of the substrate 100. For example, the resist material 400 may be applied to the substrate 100 and cured (e.g., by exposing the resist material 400 to a light source). The resist material 400 may be patterned (e.g., sized and shaped) to define cured and uncured portions of the resist material 400. For example, a gap 410 may be located between portions of the resist material 400. The resist material 410 outside of the gap 410 may be cured (e.g., where the photoresist 400 includes a positive photoresist), and uncured portions of the resist material 400 may be removed (e.g., with a solvent) to define the gap 410. The gap 410 may have a greater dimension than the recess 300.

The resist material 400 may define a resist sidewall 420, and the resist sidewall 420 may be perpendicular to (e.g., be angled at approximately 90 degrees with respect to) a surface 430 of the dielectric material 140. The resist material 400 may be located proximate to the recess 300. As described in greater detail herein, the resist material 400 may help define one or more other components of the substrate 100.

A seed layer 440 may be coupled to the substrate 100, for instance the dielectric material 140. For example, the seed layer 440 (e.g., copper, nickel, or the like) may be plated (e.g., with an electroless plating operation) onto the substrate 100. The seed layer 440 may help facilitate coupling additional conductive material to the substrate 100 (e.g., by filling the recess with a conductive material including, but not limited to, copper). The seed layer 440 may be located in the recess 300. The seed layer 440 may be coupled to the sidewall 310 of the recess 300. The seed layer 440 may be coupled with the core 120 of the substrate 100. A seam 450 may be observable at an interface between the seed layer 440 and the conductive layer 150. For example, the seam 450 may be detectable by observing the substrate 100, for instance by cross sectioning the substrate 100 and observing the substrate 100 with a microscope. A grain structure of the seed layer 450 may be different than the grain structure of the conductive layer 150.

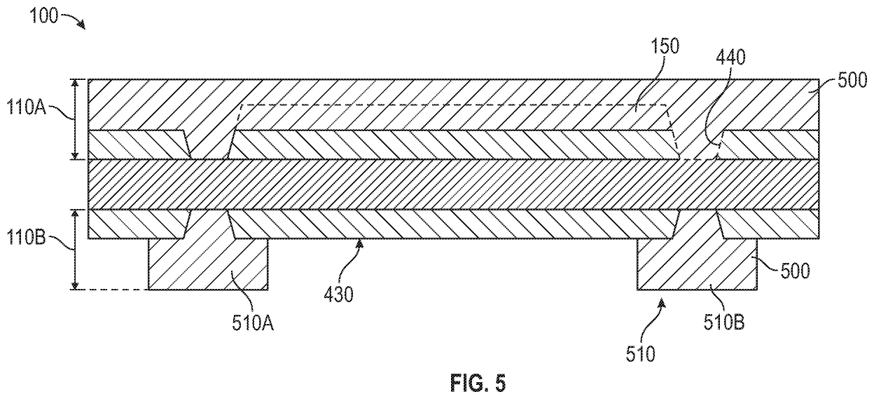

FIG. 5 illustrates an example of the substrate 100 of FIG. 1 during a manufacturing operation, according to one embodiment of the present subject matter. Conductive material 500 (e.g., copper, aluminum, nickel, gold, or the like, or a combination thereof) may be coupled to the substrate 100, for example by plating the conductive material 500 onto the substrate 100. For example, 15 micrometers of conductive material 500 may be coupled to the substrate 100. The conductive material 500 may be coupled to the first layer 110A, and may be coupled to the second layer 110B. For instance, the conductive material 500 may be coupled to the first layer 110A and the second layer 110B during the same manufacturing operation. Because the first layer 110A includes the conductive layer 150, a thickness of the first layer 110A may be different (e.g., greater) than a thickness of the second layer 110B.

The conductive material 500 may be coupled to the conductive layer 150. A seam may be detectable at the interface between the conductive layer 150. The conductive material 150 may be coupled to the seed layer 440. A seam may be detectable at the interface between the seed layer 150 and the conductive material 500. For example, the conductive material 500 may be distinguishable from the conductive layer 150 or the seed layer 440 due to differing grain structures. The conductive material 500 may be distinguishable from the conductive layer 150 or the seed layer 440 due to differing manufacturing operations used to couple the conductive material 500, the seed layer 440, or the conductive layer 150 to the substrate 100. The conductive material 500 may be distinguishable from the conductive layer 150 or the seed layer 440 due to the conductive layer 500, the seed layer 440, or the conductive layer 150 being coupled to the substrate 100 at different times (e.g., with differing manufacturing operations). The conductive material 500 and the seed layer 440 may be distinguishable from the conductive layer 150 because the conductive layer 150 may include a foil, and the grain structure of the conductive layer 150 may be elongated in comparison to the grain structure of the conductive material 500 or the grain structure of the seed layer 440.

The substrate 100 may include a first set of interconnects 510, for instance a first interconnect 510A and a second interconnect 510B. The conductive material 500 may be located in (e.g., fill, or the like) the gap 410 (shown in FIG. 4), and the resist material 400 may define the interconnects 510 (e.g., the interconnect 510A). The conductive material 500 may mimic the shape of the resist material 400. For example, the interconnects 510A may have a first interconnect profile (e.g., shape, outline, cross section, dimensions, size, or the like), and the first interconnect profile may have a rectangular shape. The first interconnect profile may be indicative of an additive manufacturing operation (e.g., a plating operating, a semi-additive build up operation, or the like). The interconnects 510A may mimic the shape of the resist sidewall 420 (shown in FIG. 4). Accordingly, portions of the interconnects 510A may be perpendicular to the surface 430 of the dielectric material 140. The resist material 400 (shown in FIG. 4) may be removed from the substrate 100, for example by applying a solvent to the resist material 400. The removal of the resist material 400 may expose the interconnects 510.

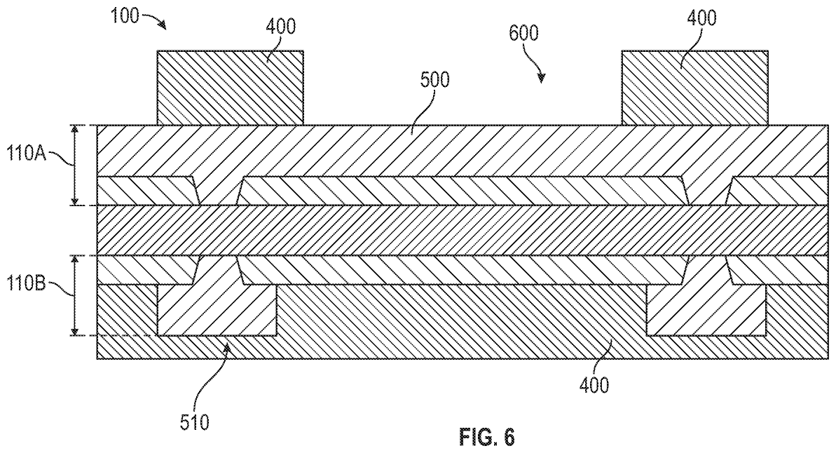

FIG. 6 illustrates an example of the substrate 100 of FIG. 1 during a manufacturing operation, according to one embodiment of the present subject matter. The resist material 400 may be coupled to the conductive material 500. The resist material 400 may be coupled to a portion of the conductive material 500. The resist material may be coupled to the first set of interconnects 510. The resist material 400 may enclose (e.g., encompass, surround, encapsulate, or the like) the interconnects 510.

The resist material 400 may protect the conductive material 500 or the interconnects 510 from one or more manufacturing operations. For example, the resist material 400 may protect the conductive material 500 or the interconnects 510 from exposure to an etchant that may etch (e.g., remove, dissolve, or the like) the conductive material 500 or the interconnects 510. Accordingly, the resist material 400 may inhibit the removal of portions of the conductive material 500 or the interconnects 510, for instance by inhibiting the interaction between the etchant and the conductive material 500 or the interconnects 510.

An etchant (e.g., an acid, or the like) may be applied to the substrate 100. For example, the etchant may be applied in a gap 600 between portions of the resist material 400. The etchant may interact with the conductive material 500, and the etchant may etch the conductive material 500. The resist material 400 may inhibit the etching of the conductive material 500 within a footprint of the resist material 400. Because the resist material 400 protects the interconnects 510 from exposure to the etchant, the etchant may not etch portions of the interconnect 510.

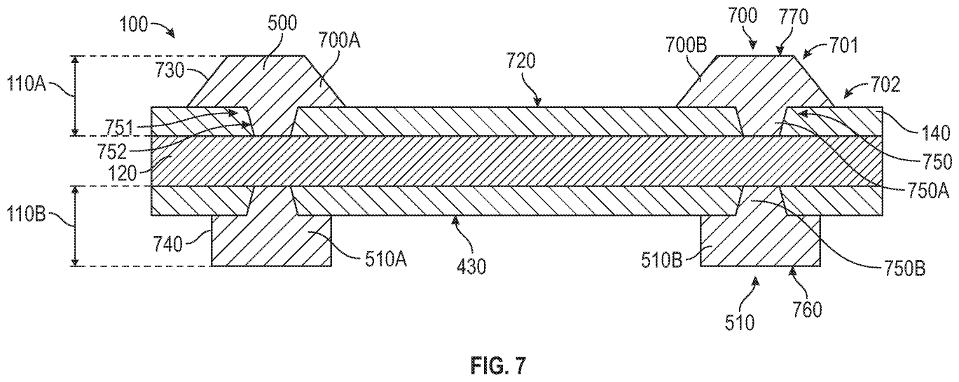

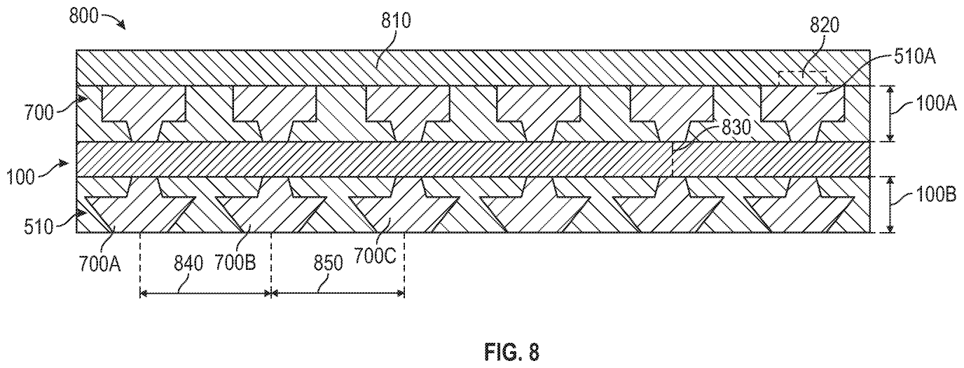

FIG. 7 illustrates an example of the substrate of FIG. 1 during a manufacturing operation, according to one embodiment of the present subject matter. As described herein, the resist material 400 (shown in FIG. 6) may protect portions of the substrate 100, for instance portions of the conductive material 500 or the first set of interconnects 510. An etchant may be applied to the substrate 100, and the etchant may remove portions of the substrate 100, for example the etchant may etch away portions of the conductive material 500 that are not protected by the resist material 400. The etchant may etch the conductive material 500, for instance the etchant may isotropically etch the conductive material 500. The etching of the conductive material 500 may provide a second set of interconnects 700, for example a third interconnect 700A and a fourth interconnect 700B. The etching of the substrate 100 may remove a portion of the conductive layer 150 (shown in FIG. 5), for example a portion of the conductive layer 150 between the interconnects 700A, 700B. Accordingly, etching of the substrate 100 may expose a surface 720 of the dielectric material 140.

The interconnects 700 may have a second interconnect profile. The second interconnect profile may be indicative of a subtractive manufacturing operation (e.g., etching, ablation, or the like). For example, etching of the conductive material 500 may provide the second interconnect profile with a trapezoidal shape, for instance because etching of the conductive material 500 may be isotropic. Accordingly, the interconnects 510 may be asymmetric to the interconnects 700, for instance because the second interconnect profile may be different than the first interconnect profile (e.g., because of differing dimensions, shapes, outlines, or the like).

The second set of interconnects 700 may be aligned with the first set of interconnects 510. For example, the second interconnect 510B may be aligned with the fourth interconnect 700B. The second set of interconnects 700 may be offset from the first set of interconnects 510. For example, the first interconnect 510A may be offset (e.g., laterally offset) from the third interconnect 700A. A footprint (e.g., width, thickness, or the like) of the third interconnect 700A may be greater than a footprint of the first interconnect 510A. The third interconnect 700A may be located within the footprint of the first interconnect 700A. A first sidewall 730 of the third interconnect 700A may be angled with respect to a second sidewall 740 of the first interconnect 510A. For instance, the sidewall 730 may be angled with respect to the surface 720 (e.g., approximately between, but not limited to, 5 degrees and 85 degrees) and the sidewall 740 may perpendicular to the surface 430 (e.g., approximately between, but not limited to, 85 degrees and 95 degrees).

The substrate 100 may include one or more vias 750, for instance a first via 750A and a second via 750B. The vias 750 may help route one or more electrical signals within the substrate 100. For example, the via 750A may electrically interconnect the core 120 with the fourth interconnect 700B. The via 750B may electrically interconnect the core 120 with the second interconnect 510B. As described herein, the recess 300 (shown in FIG. 3) may have a tapered profile. The conductive material 500 may fill the recess 300, for instance to provide the vias 750. Accordingly, the vias 750 may have a tapered profile, for instance the via 750 may have a frustoconical shape. The via 750A may be tapered in an opposite direction to an angle of the sidewall 730 of the interconnect 700B. For example, a first end 751 of the via 750A may have a greater dimension (e.g., width) than a second end 752 of the via 750A, and the via 750A may taper between the ends 751, 752. A first end 701 of the interconnect 700B may have a lesser dimension than a second end 702 of the interconnect 700B (e.g., the second end 702 is wider than the first end 701), and the angled sidewall 730 may facilitate the differing dimensions of the ends 701, 702. Accordingly, the end 751 of the via 750A with a greater dimension may be located proximate to the end 702 of the interconnect 700B with a greater dimension.

A thickness (e.g., height, or the like) of the second set of interconnects 700 may be greater than a thickness of the first set of interconnects 510. For example, the second interconnect 510B may have a thickness (e.g., a distance between the surface 430 of the dielectric material 140 and a surface 760 of the interconnect 510B) within a range of approximately 10 micrometers to 20 micrometers (e.g., 15 micrometers), however the present subject matter is not so limited. The fourth interconnect 700B may have a thickness (e.g., a distance between the surface 720 of the dielectric material 140 and a surface 770 of the interconnect 700B) within a range of approximately 20 micrometers to 30 micrometers (e.g., 25 micrometers), however the present subject matter is not so limited. The conductive layer 150 (shown in FIG. 1) may help facilitate the interconnects 700 having a greater thickness than the interconnects 510.

Increasing the thickness of the interconnects 700 may help improve the performance of the substrate 100. For example, increasing the thickness of the interconnects 700 may reduce electrical resistance of the interconnects 700 (e.g., to a direct current, an alternating current, or the like). Reducing the electrical resistance of the interconnects 700 may improve the performance of an electronic device, for example by improving the energy efficiency of the electronic device.

FIG. 8 illustrates an example of an electronic device 800, according to one embodiment of the present subject matter. The electronic device 800 may include the substrate 100. A semiconductor die 810 may be coupled to the substrate 100, and the die 810 may be in electrical communication with the substrate 100. The substrate 100 may provide a package for the die 810. The substrate 100 may route electrical signals to and from the die 810. The substrate 100 may facilitate the electrical communication between the die 810 and other components of the electronic device 800, for example a motherboard, memory, input device, or the like.

The die 810 may be coupled to the substrate 100. For example, a die interconnect 820 may be coupled with an individual one of the first set of interconnects 510 (e.g., the interconnect 510A). The first set of interconnects 700 may be in electrical communication with the second set of interconnects 510. For example, one or more traces 830 may route electrical signals between the interconnects 510, 700.

A pitch of the interconnects 510, 700 may be variable. For example, the interconnect 700A may be spaced apart from the interconnect 700B at a first pitch 840. The interconnect 700B may be spaced apart from a fifth interconnect 700C at a second pitch. The first pitch may be different than the second pitch.

Dielectric material 140 may be located between the interconnects 700. Dielectric material 140 may be located between the interconnects 510. The surface 760 of the interconnects 510 may be exposed (e.g., not enclosed by the dielectric material 140), for instance to allow the interconnects 510 to be coupled to components of the electronic device 800 (e.g., the die 810). The surface 770 of the interconnects 700 may be exposed, for instance to allow the interconnects to be coupled to components of the electronic device 800 (e.g., a motherboard, system on a chip, memory, package, or the like). The profile of the dielectric material 140 may correspond to the first interconnect profile or the second interconnect profile.

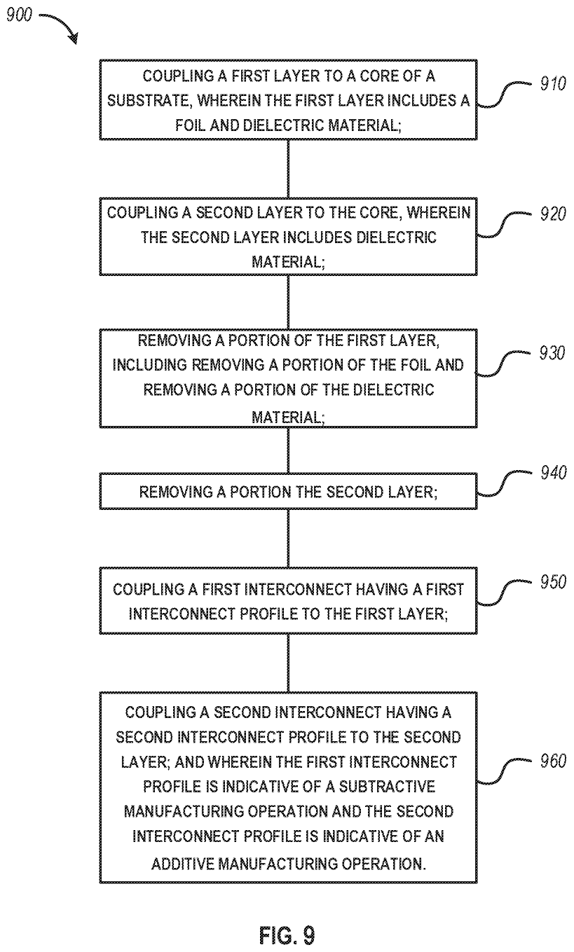

FIG. 9 shows one example of a method 900 for manufacturing an electronic device (e.g., the electronic device 800), including one or more of the substrate 100 described herein. In describing the method 900, reference is made to one or more components, features, functions and operations previously described herein. Where convenient, reference is made to the components, features, operations and the like with reference numerals. The reference numerals provided are exemplary and are not exclusive. For instance, components, features, functions, operations and the like described in the method 900 include, but are not limited to, the corresponding numbered elements provided herein and other corresponding elements described herein (both numbered and unnumbered) as well as their equivalents.

The method 900 may include at 910 coupling a first layer 110A to a core 120 of a substrate 100. The first layer 110A may include a foil (e.g., the conductive layer 150) and dielectric material 140. The foil may be coupled to the dielectric material. At 920, a second layer 110B may be coupled to the core 120. A thickness of the first layer 110A may be different than a thickness of the second layer 110B. The second layer 110B may include dielectric material 140. At 930, a portion of the first layer 110A may be removed. For instance, a portion of the foil may be removed. A portion of the dielectric material 140 may be removed. Removal of a portion of the first layer 110A may define a recess 300.

The method 900 may include at 940 that a portion of the second layer 110B may be removed. At 950, a first interconnect (e.g., the interconnect 700A) may be coupled to (or included in) the to the first layer 110A. The first interconnect may have a first interconnect profile. The first interconnect profile may be indicative of a subtractive manufacturing operation. At 960 a second interconnect (e.g., the interconnect 510A) may be coupled to (or included in) the second layer 110B. The second interconnect may have a second interconnect profile. The second interconnect profile may be indicative of an additive manufacturing operation.

Several options for the method 900 follow. For example, a portion of the first layer 110A may be etched. Etching a portion of the first layer 110A may define an angled side wall 730 of the first interconnect. A side wall 740 of the second interconnect may be perpendicular to the core 120 of the substrate 100 (or the surface 430). A first resist material 400 may be coupled to the first layer 110A. The first resist material 400 may be configured to protect a portion of the first layer 110A from etching by an etchant.

A second resist material 400 may be coupled to the second layer 110B. The second resist material 400 may be configured to protect a portion of the second layer 110B from etching by the etchant. Coupling of the first resist material 400 or the second resist material 400 may include applying a vacuum to the substrate 100. The second resist material 400 may define a portion of the second interconnect. A die interconnect 820 of a die 810 may be coupled to the first interconnect or the second interconnect of the substrate 100. Dielectric material 140 may be coupled to the first interconnect. A profile of the dielectric material 140 may at least partially corresponds to the first interconnect profile.

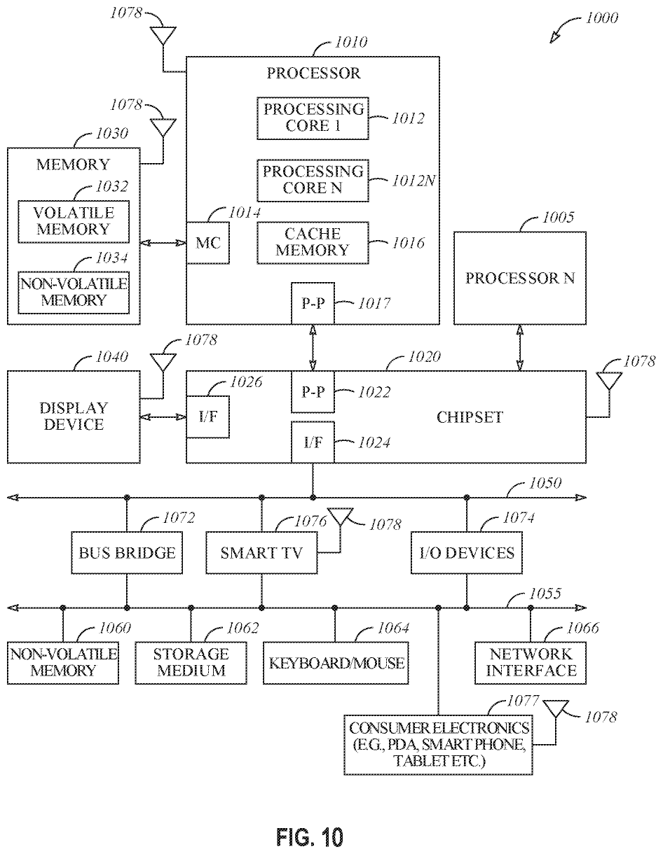

FIG. 10 illustrates a system level diagram, depicting an example of an electronic device (e.g., system) including the substrate 100 or the electronic device 800 as described in the present disclosure. FIG. 10 is included to show an example of a higher level device application for the substrate 100 or the electronic device 800. In one embodiment, system 1000 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 1000 is a system on a chip (SOC) system.

In one embodiment, processor 1010 has one or more processor cores 1012 and 1012N, where 1012N represents the Nth processor core inside processor 1010 where N is a positive integer. In one embodiment, system 1000 includes multiple processors including 1010 and 1005, where processor 1005 has logic similar or identical to the logic of processor 1010. In some embodiments, processing core 1012 includes, but is not limited to, pre-fetch logic to fetch instructions, decode logic to decode the instructions, execution logic to execute instructions and the like. In some embodiments, processor 1010 has a cache memory 1016 to cache instructions and/or data for system 1000. Cache memory 1016 may be organized into a hierarchal structure including one or more levels of cache memory.

In some embodiments, processor 1010 includes a memory controller 1014, which is operable to perform functions that enable the processor 1010 to access and communicate with memory 1030 that includes a volatile memory 1032 and/or a non-volatile memory 1034. In some embodiments, processor 1010 is coupled with memory 1030 and chipset 1020. Processor 1010 may also be coupled to a wireless antenna 1078 to communicate with any device configured to transmit and/or receive wireless signals. In one embodiment, an interface for wireless antenna 1078 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 1032 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 1034 includes, but is not limited to, flash memory, phase change memory (PCM), read-only memory (ROM), electrically erasable programmable read-only memory (EEPROM), or any other type of non-volatile memory device.

Memory 1030 stores information and instructions to be executed by processor 1010. In one embodiment, memory 1030 may also store temporary variables or other intermediate information while processor 1010 is executing instructions. In the illustrated embodiment, chipset 1020 connects with processor 1010 via Point-to-Point (PtP or P-P) interfaces 1017 and 1022. Chipset 1020 enables processor 1010 to connect to other elements in system 1000. In some embodiments of the example system, interfaces 1017 and 1022 operate in accordance with a PtP communication protocol such as the Intel® QuickPath Interconnect (QPI) or the like. In other embodiments, a different interconnect may be used.

In some embodiments, chipset 1020 is operable to communicate with processor 1010, 1005N, display device 1040, and other devices, including a bus bridge 1072, a smart TV 1076, I/O devices 1074, nonvolatile memory 1060, a storage medium (such as one or more mass storage devices) 1062, a keyboard/mouse 1064, a network interface 1066, and various forms of consumer electronics 1077 (such as a PDA, smart phone, tablet etc.), etc. In one embodiment, chipset 1020 couples with these devices through an interface 1024. Chipset 1020 may also be coupled to a wireless antenna 1078 to communicate with any device configured to transmit and/or receive wireless signals.

Chipset 1020 connects to display device 1040 via interface 1026. Display 1040 may be, for example, a liquid crystal display (LCD), a plasma display, cathode ray tube (CRT) display, or any other form of visual display device. In some embodiments of the example system, processor 1010 and chipset 1020 are merged into a single SOC. In addition, chipset 1020 connects to one or more buses 1050 and 1055 that interconnect various system elements, such as I/O devices 1074, nonvolatile memory 1060, storage medium 1062, a keyboard/mouse 1064, and network interface 1066. Buses 1050 and 1055 may be interconnected together via a bus bridge 1072.

In one embodiment, mass storage device 1062 includes, but is not limited to, a solid state drive, a hard disk drive, a universal serial bus flash memory drive, or any other form of computer data storage medium. In one embodiment, network interface 1066 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 10 are depicted as separate blocks within the system 1000, the functions performed by some of these blocks may be integrated within a single semiconductor circuit or may be implemented using two or more separate integrated circuits. For example, although cache memory 1016 is depicted as a separate block within processor 1010, cache memory 1016 (or selected aspects of 1016) can be incorporated into processor core 1012.

### Various Notes & Examples

Aspect 1 may include or use subject matter (such as an apparatus, a system, a device, a method, a means for performing acts, or a device readable medium including instructions that, when performed by the device, may cause the device to perform acts), such as may include or use a substrate for an electronic device, comprising: a first layer including dielectric material, wherein the first layer includes a first interconnect having a first interconnect profile; a second layer including dielectric material, wherein the second layer includes a second interconnect having a second interconnect profile; wherein the first interconnect profile is indicative of a subtractive manufacturing operation and the second interconnect profile is indicative of an additive manufacturing operation.

Aspect 2 may include or use, or may optionally be combined with the subject matter of Aspect 1, to optionally include or use wherein the first interconnect profile is trapezoidal in shape, and the second interconnect profile is rectangular in shape.

Aspect 3 may include or use, or may optionally be combined with the subject matter of one or any combination of Aspects 1 or 2 to optionally include or use wherein a footprint of the first interconnect is greater than a footprint of the second interconnect.

Aspect 4 may include or use, or may optionally be combined with the subject matter of one or any combination of Aspects 1 through 3 to optionally include or use wherein a first sidewall of the first interconnect is angled with respect to a second sidewall of the second interconnect.

Aspect 5 may include or use, or may optionally be combined with the subject matter of one or any combination of Aspects 1 through 4 to optionally include or use a via coupled to the first interconnect, wherein the via is tapered in an opposite direction to an angle of a sidewall of the first interconnect.

Aspect 6 may include or use, or may optionally be combined with the subject matter of one or any combination of Aspects 1 through 5 to optionally include or use a substrate core, wherein: the first layer is coupled to a first side of the core; and the second layer is coupled to a second side of the core.

Aspect 7 may include or use, or may optionally be combined with the subject matter of one or any combination of Aspects 1 through 6 to optionally include or use a seed layer coupled to the dielectric material of the first layer.

Aspect 8 may include or use, or may optionally be combined with the subject matter of one or any combination of Aspects 1 through 7 to optionally include or use a seam is located at an interface between the seed layer and a portion of the first interconnect.

Aspect 9 may include or use, or may optionally be combined with the subject matter of one or any combination of Aspects 1 through 8 to optionally include or use wherein the first interconnect is exposed on a first surface of the substrate, and the second interconnect is exposed on a second surface of the substrate.

Aspect 10 may include or use subject matter (such as an apparatus, a system, a device, a method, a means for performing acts, or a device readable medium including instructions that, when performed by the device, may cause the device to perform acts), such as may include or use a substrate for an electronic device, comprising: a first layer including dielectric material, wherein the first layer includes a first set of interconnects includes a first interconnect, wherein the first interconnect has a first interconnect profile; a second layer including dielectric material, wherein the second layer includes a second set of interconnects including a second interconnect, and the second interconnect has a second interconnect profile; and wherein the first interconnect profile is indicative of a subtractive manufacturing operation and the second interconnect profile is indicative of an additive manufacturing operation.

Aspect 11 may include or use, or may optionally be combined with the subject matter of Aspect 10, to optionally include or use wherein the first interconnect profile is trapezoidal, and the second interconnect profile is rectangular.

Aspect 12 may include or use, or may optionally be combined with the subject matter of one or any combination of Aspects 10 or 11 to optionally include or use a seed layer coupled to the dielectric material of the first layer.

Aspect 13 may include or use, or may optionally be combined with the subject matter of one or any combination of Aspects 10 through 12 to optionally include or use wherein: the first set of interconnects includes a third interconnect having the first interconnect profile; the first set of interconnects includes a fourth interconnect having the first interconnect profile; the first interconnect is space apart from the third interconnect at a first pitch; and the third interconnect is spaced apart from the fourth interconnect at a second pitch.

Aspect 14 may include or use, or may optionally be combined with the subject matter of one or any combination of Aspects 10 through 13 to optionally include or use wherein the first interconnect is in electrical communication with the second electrical interconnect.

Aspect 15 may include or use, or may optionally be combined with the subject matter of one or any combination of Aspects 10 through 14 to optionally include or use a substrate core, wherein: the first layer is coupled to a first side of the core; the second layer is coupled to a second side of the core; and the substrate core includes a cloth material impregnated with dielectric material.

Aspect 16 may include or use, or may optionally be combined with the subject matter of one or any combination of Aspects 10 through 15 to optionally include or use a semiconductor die in electrical communication with the substrate.

Aspect 17 may include or use subject matter (such as an apparatus, a system, a device, a method, a means for performing acts, or a device readable medium including instructions that, when performed by the device, may cause the device to perform acts), such as may include or use a method for manufacturing an electronic device, comprising: coupling a first layer to a core of a substrate, wherein the first layer includes a foil and dielectric material; coupling a second layer to the core, wherein the second layer includes dielectric material; removing a portion of the first layer, including removing a portion of the foil and removing a portion of the dielectric material; removing a portion the second layer; coupling a first interconnect having a first interconnect profile to the first layer; coupling a second interconnect having a second interconnect profile to the second layer; and wherein the first interconnect profile is indicative of a subtractive manufacturing operation and the second interconnect profile is indicative of an additive manufacturing operation.

Aspect 18 may include or use, or may optionally be combined with the subject matter of Aspect 17, to optionally include or use etching a portion of the first layer, wherein etching a portion of the first layer defines an angled side wall of the first interconnect.

Aspect 19 may include or use, or may optionally be combined with the subject matter of one or any combination of Aspects 17 or 18 to optionally include or use wherein a side wall of the second interconnect is perpendicular to the core of the substrate.

Aspect 20 may include or use, or may optionally be combined with the subject matter of one or any combination of Aspects 17 through 19 to optionally include or use coupling a first resist material to the first layer, wherein first resist material is configured to protect a portion of the first layer from etching by an etchant.

Aspect 21 may include or use, or may optionally be combined with the subject matter of Aspect 20 to optionally include or use coupling a second resist material onto the second layer, wherein the second resist material is configured to protect a portion of the second layer from etching by the etchant.

Aspect 22 may include or use, or may optionally be combined with the subject matter of one or any combination of Aspects 20 or 21 to optionally include or use wherein coupling the first resist material includes applying a vacuum to the substrate.

Aspect 23 may include or use, or may optionally be combined with the subject matter of one or any combination of Aspects 17 through 22 to optionally include or use coupling a second resist material to the second layer, wherein the second resist material defines a portion of the second interconnect.

Aspect 24 may include or use, or may optionally be combined with the subject matter of one or any combination of Aspects 17 through 23 to optionally include or use coupling the foil to the dielectric material.

Aspect 25 may include or use, or may optionally be combined with the subject matter of one or any combination of Aspects 17 through 24 to optionally include or use wherein a thickness of the first layer is different than a thickness of the second layer.

Aspect 26 may include or use, or may optionally be combined with the subject matter of one or any combination of Aspects 17 through 25 to optionally include or use coupling a die interconnect of a die to the first interconnect or the second interconnect of the substrate.

Aspect 27 may include or use, or may optionally be combined with the subject matter of one or any combination of Aspects 17 through 26 to optionally include or use coupling dielectric material to the first substrate, wherein a profile of the dielectric material at least partially corresponds to the first interconnect profile.

Aspect 28 may include or use, or may optionally be combined with any portion or combination of any portions of any one or more of Aspects 1 through 27 to include or use, subject matter that may include means for performing any one or more of the functions of Aspects 1 through 27, or a machine-readable medium including instructions that, when performed by a machine, cause the machine to perform any one or more of the functions of Aspects 1 through 27.

Each of these non-limiting aspects can stand on its own, or can be combined in various permutations or combinations with one or more of the other aspects.

The above description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls. In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A substrate for an electronic device, comprising:
a first layer including dielectric material, wherein the first layer includes a first interconnect having a first interconnect profile;
a second layer including dielectric material, wherein the second layer includes a second interconnect having a second interconnect profile;
wherein the first interconnect profile is indicative of a subtractive manufacturing operation and the second interconnect profile is indicative of an additive manufacturing operation.

2. The substrate of claim 1, wherein the first interconnect profile is trapezoidal in shape, and the second interconnect profile is rectangular in shape.

3. The substrate of claim 1, wherein a footprint of the first interconnect is greater than a footprint of the second interconnect.

4. The substrate of claim 1, wherein a first sidewall of the first interconnect is angled with respect to a second sidewall of the second interconnect.

5. The substrate of claim 1, further comprising a via coupled to the first interconnect, wherein the via is tapered in an opposite direction to an angle of a sidewall of the first interconnect.

6. The substrate of claim 1, further comprising a substrate core, wherein:
the first layer is coupled to a first side of the core; and
the second layer is coupled to a second side of the core.

7. The substrate of claim 1, further comprising a seed layer coupled to the dielectric material of the first layer.

8. The substrate of claim 7, wherein a seam is located at an interface between the seed layer and a portion of the first interconnect.

9. The substrate of claim 1, wherein the first interconnect is exposed on a first surface of the substrate, and the second interconnect is exposed on a second surface of the substrate.

10. A substrate for an electronic device, comprising:
a first layer including dielectric material, wherein the first layer includes a first set of interconnects includes a first interconnect, wherein the first interconnect has a first interconnect profile;
a second layer including dielectric material, wherein the second layer includes a second set of interconnects including a second interconnect, and the second interconnect has a second interconnect profile; and
wherein the first interconnect profile is indicative of a subtractive manufacturing operation and the second interconnect profile is indicative of an additive manufacturing operation.

11. The substrate of claim 10, wherein the first interconnect profile is trapezoidal, and the second interconnect profile is rectangular.

12. The substrate of claim 10, further comprising a seed layer coupled to the dielectric material of the first layer.

13. The substrate of claim 10, wherein:
the first set of interconnects includes a third interconnect having the first interconnect profile;
the first set of interconnects includes a fourth interconnect having the first interconnect profile;
the first interconnect is space apart from the third interconnect at a first pitch; and
the third interconnect is spaced apart from the fourth interconnect at a second pitch.

14. The substrate of claim 10, wherein the first interconnect is in electrical communication with the second electrical interconnect.

15. The substrate of claim 10, further comprising a substrate core, wherein:
the first layer is coupled to a first side of the core;
the second layer is coupled to a second side of the core; and
the substrate core includes a cloth material impregnated with dielectric material.

16. The substrate of claim 10, further comprising a semiconductor die in electrical communication with the substrate.

17. A method for manufacturing an electronic device, comprising:
coupling a first layer to a core of a substrate, wherein the first layer includes a foil and dielectric material;
coupling a second layer to the core, wherein the second layer includes dielectric material;
removing a portion of the first layer, including removing a portion of the foil and removing a portion of the dielectric material;
removing a portion the second layer;
coupling a first interconnect having a first interconnect profile to the first layer;
coupling a second interconnect having a second interconnect profile to the second layer; and
wherein the first interconnect profile is indicative of a subtractive manufacturing operation and the second interconnect profile is indicative of an additive manufacturing operation.

18. The method of claim 17, further comprising etching a portion of the first layer, wherein etching a portion of the first layer defines an angled side wall of the first interconnect.

19. The method of claim 17, wherein a side wall of the second interconnect is perpendicular to the core of the substrate.

20. The method of claim 17, further comprising coupling a first resist material to the first layer, wherein first resist material is configured to protect a portion of the first layer from etching by an etchant.

21. The method of claim 20, further comprising coupling a second resist material onto the second layer, wherein the second resist material is configured to protect a portion of the second layer from etching by the etchant.

22. The method of claim 20, wherein coupling the first resist material includes applying a vacuum to the substrate.

23. The method of claim 17, further comprising coupling a second resist material to the second layer, wherein the second resist material defines a portion of the second interconnect.

24. The method of claim 17, further comprising coupling the foil to the dielectric material.

25. The method of claim 17, wherein a thickness of the first layer is different than a thickness of the second layer.
